(19) United States
(12) Patent Application Publication
(10) Pub. No.: US 2025/0393233 A1
(43) Pub. Date: Dec. 25, 2025

(54) MODIFYING FINFET FINS FROM BACKSIDE

(71) Applicant: International Business Machines Corporation, Armonk, NY (US)

(72) Inventors: Gopal Sankar Kenath, Troy, NY (US); Tao Li, Slingerlands, NY (US); Ruilong Xie, Niskayuna, NY (US); Jingyun Zhang, Albany, NY (US)

(21) Appl. No.: 18/749,814

(22) Filed: Jun. 21, 2024

(51) Int. Cl. H01L 29/66; H01L 21/8238; H01L 23/528; H01L 27/092; H01L 29/417; H01L 29/78

(52) U.S. Cl. CPC H10D 30/024; H01L 23/5283; H10D 30/6211; H10D 30/6219; H10D 84/0188; H10D 84/0193; H10D 84/038; H10D 84/853

(57) ABSTRACT

A semiconductor IC device is presented and includes a first region and a second region. The first region includes a first fin upon a backside interlayer dielectric (ILD) comprising a first fin height or a first effective channel width. The second region includes a second fin upon the backside ILD comprising a second fin height or a second effective channel width that is less than the first fin height or the second effective channel width, respectively. The reduced second fin height or a second effective channel width may be provided by processing the second fin from the backside of the semiconductor IC device.

### BACKGROUND

Semiconductor integrated circuit (IC) devices have become ubiquitous within many products, particularly as they continue to decrease in cost and size. There is a continued desire to reduce the size of structural features and/or to provide a greater amount of structural features for a given device size. Miniaturization, in general, allows for increased performance at lower power levels and lower cost. Present technology is at or approaching atomic level scaling of certain micro-devices such as FinFETs, or the like.

To achieve expected FinFET functionality, the gate electric field should typically control the fin channel, which may be referred herein as simply channel, and the drain electric field should have a lesser effect on the channel. Otherwise, the FinFET will show a set of unwanted effects called short channel effects. One way to reduce the propensity of short channel effects is to increase the effective gate width, which is a dimension of the vertical periphery of the gate along both sides of the fin (i.e., two times the height of the fin) plus the horizontal thickness of the fin. For clarity, the effective gate width may also be referred herein as the effective channel width. However, in some applications, a relatively large effective channel width may not be desirable.

### SUMMARY

The present disclosure relates to fabrication methods and resulting structures for semiconductor integrated circuit (IC) devices. More specifically, the present disclosure relates to fabrication methods and resulting semiconductor IC devices that include a FinFET that have channels that can have relatively different or variable channel heights and/or different effective channel widths. This allows for fins to be fabricated in first region(s) that have a relatively large effective channel widths/channel heights and also allows for fins to be fabricated in second region(s) that have a relative smaller effective channel widths/channel heights.

In an embodiment of the disclosure, a semiconductor IC device is presented. The semiconductor IC device includes a first region and a second region. The first region includes a first fin upon a backside ILD that has a first fin height. The second region includes a second fin upon the backside ILD that has a second fin height that is less than the first fin height.

In an embodiment of the disclosure, a semiconductor IC device is presented. The semiconductor IC device includes a first FinFET and a second FinFET. The first FinFET includes a first fin upon a backside ILD and has a first effective channel width. The second FinFET includes a second fin upon the backside ILD and has a second effective channel width that is less than the first effective channel width.

In an embodiment of the disclosure, a semiconductor IC device fabrication method is presented. The method includes forming a pair of fins within a substrate structure, forming a fin plug between the pair of fins. The method further includes, after growing the fin plug, forming STI openings within the substrate structure below and adjacent to the pair of fins and forming a respective STI region within the STI openings.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts cross-sectional views a semiconductor IC device that includes FinFETs that have channel(s) that can have relatively different or variable channel heights, according to embodiments of the disclosure.

FIG. 2 depicts a partial top down view of a semiconductor IC device that includes FinFETs that have channel(s) that can have relatively different or variable channel heights, according to embodiments of the disclosure.

FIG. 3 through FIG. 14 depict respective fabrication cross-sectional views of a semiconductor IC device that includes FinFETs that have channel(s) that can have relatively different or variable channel heights, according to embodiments of the disclosure.

FIG. 15 depicts a method of fabricating a semiconductor IC device that includes FinFET that have channel(s) that can have relatively different or variable channel heights, according to embodiments of the disclosure.

### DETAILED DESCRIPTION

Aspects of the disclosure may limit short channel effects within FinFETs and may allow for further scaling of FinFETs. More specifically, a semiconductor IC device that includes a first region and a different second region. The first region includes a first fin upon a backside interlayer dielectric (ILD). The first fin has a first fin height. The second region includes a second fin upon the backside ILD. The second fin has a second fin height that is less than the first fin height. Therefore, the semiconductor IC device provides flexibility in achieving variable or different fin heights or effective channel widths in different areas or regions of the semiconductor IC device which may increase semiconductor IC device fabrication efficiency, yield, and/or performance.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions.

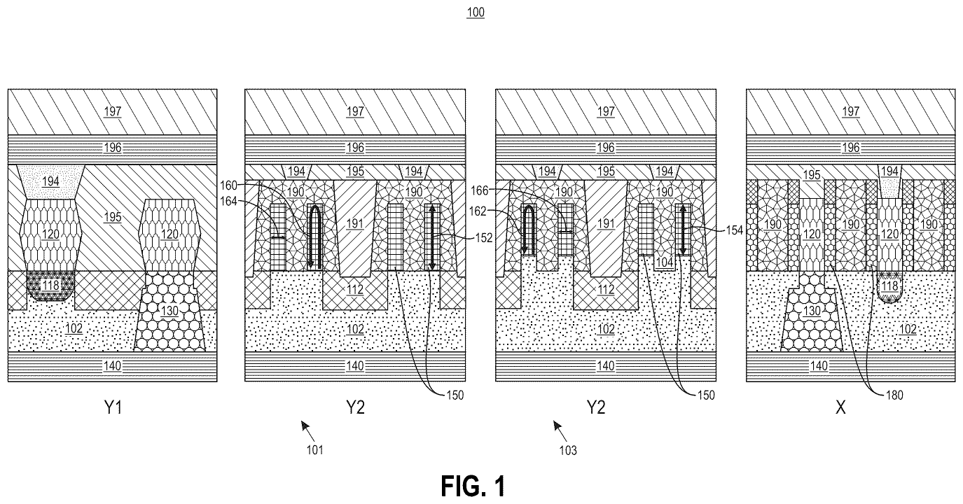

Referring now to the drawings in which like numerals represent the same or similar elements and initially to FIG. 1 which depicts cross-sectional views a semiconductor IC device 100. The semiconductor device 100 may include backside interlayer dielectric (ILD) 102, one or more STI regions 112, one or more source/drain regions 120, one or more backside contact placeholders 118, one or more replacement gate structures 190, one or more gate inner spacers 180, one or more gate cut regions 191, one or more frontside ILD instances 195, one or more frontside contacts 194, a frontside back end of line (BEOL) network 196, carrier wafer 197, one or more backside contacts 130, and/or a backside BEOL network 140.

The FinFETs within the semiconductor IC device 100 may utilize one or more of the above recited structures. For example, the channel(s) 150 may be connected to the source/drain regions 120 and to the replacement gate structure 190, the gate inner spacers 180 may adequately electrically isolate the replacement gate structure 190 from the respective source/drain regions 120, a respective frontside contact 194 may electrically connect an underlying region to the frontside BEOL network 196, a respective backside contact 130 may electrically connect an above region to the backside BEOL network 140, etc.

In an embodiment of the present disclosure, a particular instance of semiconductor IC device 100 is presented. The semiconductor IC device 100 includes a first region 101 (e.g., a first Y2 section) and a second region 103 (e.g., a second Y2 section). The regions 101, 103 include one or more transistors (e.g., FinFETs) with channels 150 that have relatively different or variable channel heights 152, 154. For example, the first region 101 has a first fin (i.e. a first channel 150) that is upon the backside ILD 102 that has a first fin height 152 and the second region 103 has a second fin (i.e. second channel 150) upon the backside ILD 102 that has a second fin height 154 that is less than the first fin height 152.

The semiconductor IC device 100 provides flexibility in achieving variable or different fin heights 152, 154 in different areas or regions 101, 103 of the semiconductor IC device 100, which may increase semiconductor IC device 100 fabrication efficiency, yield, and/or performance. For example, the different fin heights 152, 154 may enable flexibility of semiconductor IC device 100 macro designs or applications, such as SRAM, or the like.

In an example, a top surface of the first fin is coplanar with a top surface of the second fin. The coplanarity of the top surfaces of the channels 150 in the different regions 101, 103 may result from the processing of the channels 150 from the backside of semiconductor IC device 100.

In an example, first STI regions 112 at least partially bounds the first region 101, and the first region 101 further comprises a first FinFET that includes first source/drain (S/D) regions 120 and the first fin. In other words, the first FinFET may be at least partially formed to include the first source/drain regions 120 which may be directly connected to respective end surfaces of the first fin.

In an example, second STI regions 112 at least partially bounds the second region 103, and the second region 103 further includes a second FinFET that includes second source/drain regions 120 and the second fin. In other words, the second FinFET may be at least partially formed to include the second source/drain regions 120 which may be directly connected to respective end surfaces of the second fin.

In an example, a bottom surface of the first fin is substantially coplanar with a top surface of the first STI regions 112. For example, the bottom surface of the first fin is at or near the top surface of the first STI regions 112.

In an example, a bottom surface of the second fin is above a top surface of the second STI regions 112. For example, the bottom surface of the second fin is above the top surface of the second STI regions 112. In such example, the fin height 154 may be relatively inset from the top surface of the second STI regions 112 due to processing the channels 150 in the second region 103 from the backside of the semiconductor IC device 100.

In an example, the top surface of the first STI regions 112 and the top surface of the second STI regions 112 are substantially coplanar. For example, the first STI regions 112 and the second STI regions 112 may be formed in the same or similar fabrication processes and may be structurally and/or geometrically the same or similar.

In an example, the first FinFET further includes a first gate (i.e., a first replacement gate structure 190) and wherein a bottom surface of the first gate is substantially coplanar with the bottom surface of the first fin. For example, the bottom surface of the replacement gate may be utilized as an etch stop to stop the processing of the channels 150 from the backside of semiconductor IC device 100 within the first region 101. The replacement gate structures 190 may a tri-gate in that such replacement gate structures 190 contacts three sides of the respective channels 150.

In an example, the second FinFET further includes a second gate (i.e., a second replacement gate structure 190) and wherein a bottom surface of the second gate is substantially coplanar with the top surface of the second STI regions 112. For example, the etch that processes the channels 150 from the backside of semiconductor IC device 100 within the second region 103 may be controlled to reduce the channels 150 past the bottom surface of the second gate.

In an example, the backside ILD 102 comprises a backside ILD portion 104 between the bottom surface of the second fin and the top surface of the second STI regions 112. The backside ILD portion 104 may be formed by the deposition of the backside ILD 102 upon the backside of the semiconductor IC device 100 after the channels 150 are processed from the backside of the semiconductor IC device 100 in the second region 103.

In an example, the semiconductor IC device 100 further includes the frontside BEOL network 196 and the backside BEOL network 140. The backside BEOL network 140 may further allow for the full or partial decoupling of signal routing and/or power routing and/or allows for dividing or splitting power wires and/or signal wires between both the frontside and backside of the semiconductor IC device 100. By incorporating the backside BEOL network 140, routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

In an example, the first gate and the second gate are respectively electrically connected to the frontside BEOL network 196. For example, the first gate and the second gate may be electrically connected to the frontside BEOL network 196 by respective one or more frontside contacts 194, for example, to take advantage of the full or partial decoupling of signal routing and/or power routing between the frontside BEOL network 196 and the backside BEOL network 140.

In an example, one of the first S/D regions 120 is electrically connected to the frontside BEOL network 196 by a frontside contact 194 and another of the first S/D regions 120 is electrically connected to the backside BEOL network 140 by a backside contact 130 to take advantage of the full or partial decoupling of signal routing and/or power routing between the frontside BEOL network 196 and the backside BEOL network 140.

In an example, wherein the first FinFET further includes a first gate inner spacer 180 in contact with a sidewall of the first gate and with a sidewall of one of the first S/D regions 120 and a second gate inner spacer 180 in contact with an opposite sidewall of the first gate and with a sidewall of another of the first S/D regions 120. The gate inner spacers 180 may adequately electrically isolate the replacement gate structure 190 from the respective source/drain regions 120.

In an embodiment of the present disclosure, another instance of semiconductor IC device 100 is presented. The semiconductor IC device 100 includes a first FinFET that includes a first fin (i.e., first channel 150) upon the backside ILD 102. The first fin includes a first effective channel width 160. The semiconductor IC device 100 includes a second FinFET that has a second fin (i.e., first channel 150) upon the backside ILD 102. The second fin includes a second effective channel width 162 that is less than the first effective channel width 160.

The semiconductor IC device 100 provides flexibility in achieving variable or different fin heights 152, 154 in different areas or regions 101, 103 of the semiconductor IC device 100, which may increase semiconductor IC device 100 fabrication efficiency, yield, and/or performance. For example, the different fin heights 152, 154 may enable flexibility of semiconductor IC device 100 macro designs or applications, such as SRAM, or the like.

In an example, a top surface of the first fin is coplanar with a top surface of the second fin. The coplanarity of the top surfaces of the channels 150 may result from the processing of the channels of the second FinFET from the backside of semiconductor IC device 100.

In an example, a first fin thickness 164 is substantially the same as a second fin thickness 166. As such, the effective channel width 162 is less than the first effective channel width 160 due to the relative fin heights 152, 154 of the channels 150.

In an embodiment of the present disclosure, a semiconductor IC device fabrication method is presented. The method includes forming a pair of fins (i.e., channels 150) within a substrate structure. The method includes forming a fin plug between the pair of fins. The method further includes, after growing the fin plug, forming STI openings within the substrate structure below and adjacent to the pair of channels 150. The method further includes forming a respective STI region 112 within the STI openings. The fin plug may effectively structurally tie the pair of channels 150 together prior to forming a sacrificial gate structure therearound. The substrate structure beneath the fin plug and the pair of fins may be processed differently in different regions of the semiconductor IC device. The processing of this substrate structure region provides flexibility in achieving variable or different fin heights 152, 154 in the different regions.

In an example, the method further includes, from a backside of the semiconductor IC device, removing the substrate structure between the STI regions below the pair of fins. The removal of the substrate structure region provides flexibility in achieving variable or different fin heights 152, 154 in the different regions.

In an example, the removing the substrate structure between the STI regions below the pair of fins further includes further removing a respective portion of the pair of channels 150 above the STI regions 112. In this manner, fin height 154 may be achieved by removing the respective portions of the pair of channels 150 above the STI regions 112.

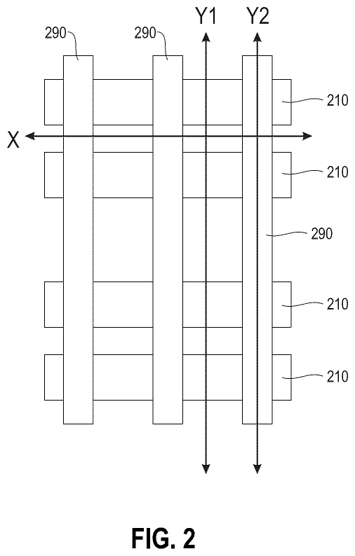

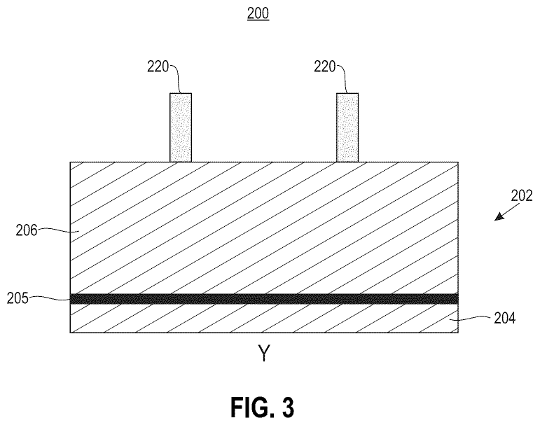

FIG. 2 depicts a partial top down view of a semiconductor IC device 200 that includes or is to include FinFETs that have channel(s) that can have relatively different or variable channel heights, according to embodiments of the disclosure. As currently depicted, semiconductor IC device 200 include a pair or adjacent fins 210 and replacement gate structures 290. FIG. 2 also depicts various cross-sectional planes of the various cross-sectional views of FIG. 3 through FIG. 13. The X cross-sectional plane is between adjacent fins 210 and across replacement gate structures 290. The Y1 cross-sectional plane is between adjacent replacement gate structures 290 and across fins 210. The Y2 cross-sectional plane is through a replacement gate structure 290 and across fins 210.

FIG. 3 depicts an initial fabrication cross-sectional view of semiconductor IC device 200 that includes or is to include FinFETs that have channel(s) that can have relatively different or variable channel heights, according to embodiments of the disclosure. At the present fabrication stage, fin mandrels 220 may be formed over a substrate structure 202.

The substrate structure 202 may include a semiconductor material including, but not limited to, silicon (Si), silicon germanium (SiGe), silicon carbide (SiC), Si:C (carbon doped silicon), silicon germanium carbide (SiGeC), carbon doped silicon germanium (SiGe:C), III-V, II-V compound semiconductor or other like semiconductor. In addition, multiple layers of the semiconductor materials can be used as the semiconductor material of the substrate structure 202. The substrate structure 202 can be a bulk substrate, or a semiconductor-on-insulator substrate such as, but not limited to, a silicon-on-insulator (SOI), silicon-germanium-on-insulator (SGOI) or III-V-on-insulator substrate including a buried insulating layer, such as, for example, a buried oxide or nitride layer. In the depicted implementation, the substrate structure 202 includes an upper substrate 206, a lower substrate 204, and an etch stop layer 205 between the upper substrate 206 and the lower substrate 204. The upper substrate 206 and the lower substrate 204 may be comprised of any suitable material(s) including those listed above, and the etch stop layer 205 may be a dielectric material with etch selectivity to one or both of the upper substrate 206 and/or the lower substrate 204. In an example, the lower substrate 204 may be composed of Si. The etch stop layer 205 may be composed of SiGe and may be epitaxially grown from the top surface of lower substrate 204 and the upper substrate 206 may be composed of Si and may be epitaxially grown from the top surface of etch stop layer 205.

The one or more fin mandrels 220 may comprise, but are not necessarily limited to, amorphous silicon (a-Si), amorphous carbon, polycrystalline silicon, polycrystalline silicon germanium, amorphous silicon germanium, polycrystalline germanium, and/or amorphous germanium, are formed on the substrate structure 202 and spaced apart from each other. The fin mandrel 220 formation can be done by various patterning techniques, including, but not necessarily limited to, lithography patterning followed by directional etching and/or a sidewall image transfer (SIT) process, for example. In some embodiments, the process includes depositing a blanket of fin mandrel 220 material and using lithography followed by directional etching (e.g., RIE, or the like) to form the one or more fin mandrels 220. The fin mandrels 220 may have a dimension that may effectively define a distance between a pair or otherwise adjacent fins 210.

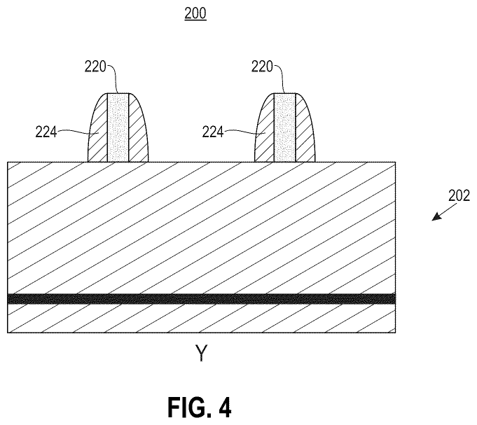

FIG. 4 depicts a fabrication cross-sectional view of semiconductor IC device 200 that includes or is to include FinFETs that have channel(s) that can have relatively different or variable channel heights, according to embodiments of the disclosure. At the present fabrication stage, sidewall image transfer (SIT) spacer(s) 224 may be formed upon the sidewall(s) of the fin mandrels 220.

The SIT spacer(s) 224 may be a conformal film and can be deposited and then followed by an etch back process (e.g., RIE, or the like). The deposition of material upon the mandrel 220 may also be referred to as spacer formation around vertical sides of each mandrel 220. The SIT spacer(s) 224 material can include, but is not limited, an oxide, such as silicon oxide (SiOₓ) (where x is, for example, 2 in the case of silicon dioxide (SiO₂), or 1.99 or 2.01), formed by low-pressure chemical vapor deposition (LPCVD), PECVD, sub-atmospheric chemical vapor deposition (SACVD), rapid thermal chemical vapor deposition (RTCVD), in-situ radical assisted deposition, high temperature oxide (HTO) deposition, low temperature oxide (LTO) deposition, ozone/TEOS deposition, limited reaction processing CVD (LRPCVD). Alternatively, some other dielectric materials, such as SiOCN, SiCN, SiOC, can be used as the material for SIT spacer(s) 224. A height of the mandrels 220 and corresponding SIT spacer(s) 224 can be in the range of, but is not necessarily limited to, 30 nm to 100 nm.

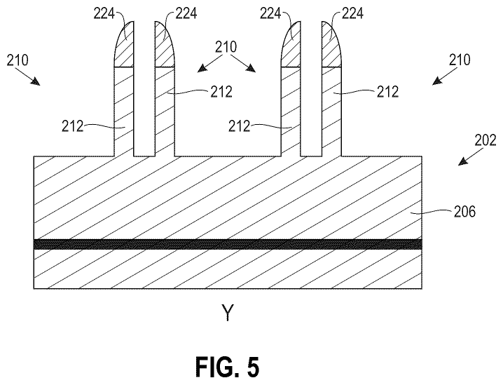

FIG. 5 depicts a fabrication cross-sectional view of semiconductor IC device 200 that includes or is to include FinFETs that have channel(s) that can have relatively different or variable channel heights, according to embodiments of the disclosure. At the present fabrication stage, the one or more mandrels 220 are removed and respective upper portions 212 of the fins 210 may be formed.

Respective upper portion(s) 212 of fins 210 may be formed by patterning part of the substrate structure 202, such as upper substrate 206, into the respective upper portion(s) 212 of fins 210. The respective upper portion(s) 212 of fins 210 may be formed by removal of the mandrels 220 which expose portions of a top surface of the substrate structure 202.

The respective upper portion(s) 212 of fins 210 may be formed by patterning part of the substrate structure 202, such as upper substrate 206, into the respective upper portion(s) 212 of fins 210. The selective removal of the mandrels 220 leaves the SIT spacer(s) 224 on the substrate structure 202. Portions of the substrate structure 202 may be removed to certain depth (depending on design) using a substrate etch. The substrate etch may transfer the pattern of the SIT spacer(s) 224 to the substrate structure 202 to form the respective upper portion(s) 212 of fins 210. For clarity, the present disclosure illustrates the channels as fins 210, and although a finite number of fins 210 are shown in the figures for ease of explanation, more or fewer fins 210 can be formed.

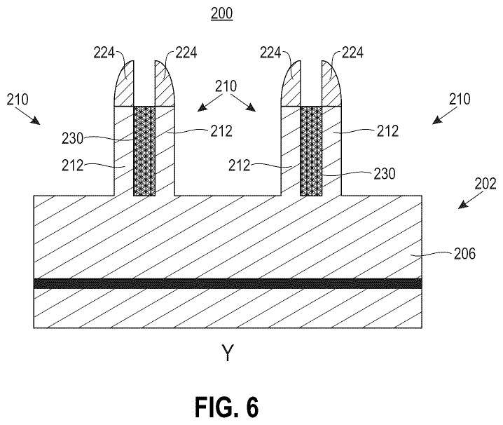

FIG. 6 depicts a fabrication cross-sectional view of semiconductor IC device 200 that includes or is to include FinFETs that have channel(s) that can have relatively different or variable channel heights, according to embodiments of the disclosure. At the present fabrication stage, a fin plug 230 may be formed between respective upper portions 212 of adjacent or a pair fins 210.

The fin plug(s) 230 may consist of a semiconductor material, such as SiGe. In an example, the fin plug(s) may be deposited upon the substrate structure 202 between respective upper portions 212 of adjacent or a pair of fins 210 by a blanket deposition and a subsequent etch back to remove undesired fin plug(s) 230 material.

In another example, the fin plug(s) 230 may be epitaxially grown from the substrate structure 202 and/or from respective side surfaces of the upper portions 212 of adjacent or a pair of fins 210 followed by a etch back to remove undesired fin plug(s) 230 material. In some embodiments, epitaxial growth and/or deposition processes may be selective to forming on semiconductor surfaces, and may not deposit material on dielectric surfaces, such as silicon dioxide or silicon nitride surfaces.

In certain implementations, the fin plug(s) 230 may be formed or otherwise retained between and contacting respective sidewalls of the upper portions 212 of adjacent or pair of fins 210 and upon and contacting a top surface of the upper substrate 206 or, generally, substrate structure 202. The top surface(s) of the fin plug(s) 230 may be substantially coplanar with or below one or more respective top surfaces of the upper portions 212 of adjacent or pair of fins 210. In examples, a respective fin plug 230 structurally joins or otherwise associates the adjacent or pair of fins 210 and may be referred herein as a channel row, at the present fabrication stage. In examples, the fin plug(s) 230 may serve as a etch mask so as to retain the portion of the substrate structure 202 thereunder in subsequent processing of the semiconductor IC device 200.

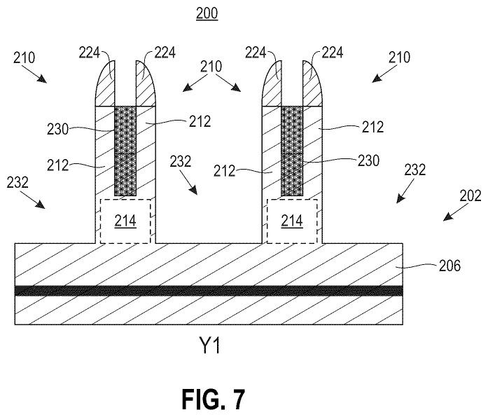

FIG. 7 depicts a fabrication cross-sectional view of semiconductor IC device 200 that includes or is to include FinFETs that have channel(s) that can have relatively different or variable channel heights, according to embodiments of the disclosure. At the present fabrication stage, substrate structure 202 may be partially recessed outside of the adjacent fins 210 to form one or more shallow trench isolation (STI) region openings 232.

The STI region openings 232 may be formed by a directional etching technique (e.g., RIE, or the like) that utilizes the SIT spacer(s) 224 and the fin plug(s) 230 as etch masks. The SIT spacer(s) 224 may protect the underlying upper portions 212 of the pair of fins 210 and the fin plug(s) 230 may protect the underlying substrate structure 202 from the directional etch. Resultantly, a portion of the substrate structure 202 under the upper portions 212 of the adjacent or pair of fins 210 and under the fin plug(s) 230 may be retained and may form a lower portion 214 of the pair of fins 210. For example, a portion of the upper substrate 206 under the upper portions 212 of the adjacent or pair of fins 210 and under the fin plug(s) 230 may be retained. A bottom or well surface of the STI region openings 232 may be above the etch stop layer 205.

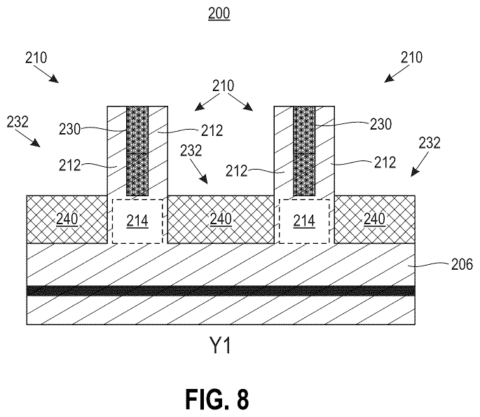

FIG. 8 depicts a fabrication cross-sectional view of semiconductor IC device 200 that includes or is to include FinFETs that have channel(s) that can have relatively different or variable channel heights, according to embodiments of the disclosure. At the present fabrication stage, a STI region 240 may be formed within respective STI region openings 232 and the SIT spacer(s) 224 may be removed.

The STI region(s) 240 may be formed by depositing a dielectric material including, but not necessarily limited to SiOₓ, LTO, HTO, flowable oxide (FOX), SiOC, SiOCN, or some other dielectric, into the STI region openings 232. The dielectric material can be deposited using deposition techniques including, but not necessarily limited to, CVD, plasma enhanced CVD, PECVD, RFCVD, PVD, ALD, MLD, MBD, PLD, LSMCD. As depicted, top surfaces of the STI region(s) 240 may be substantially coplanar with the respective bottom surfaces of the upper portions 212 of the pair of fins 210 and/or the fin plug(s) 230. The STI region(s) 240 may directly contact the top surface of the recessed upper substrate 206 and respective sidewalls of the lower portion 214 of the pair of fins 210. In some examples, an STI region 240 may adequately electrically isolate a first cell that includes one or more FinFETs from a second cell that includes one of more FinFETs. The STI region 240 may also at least partially define or establish respective geometrical and/or structural boundaries of the cell(s).

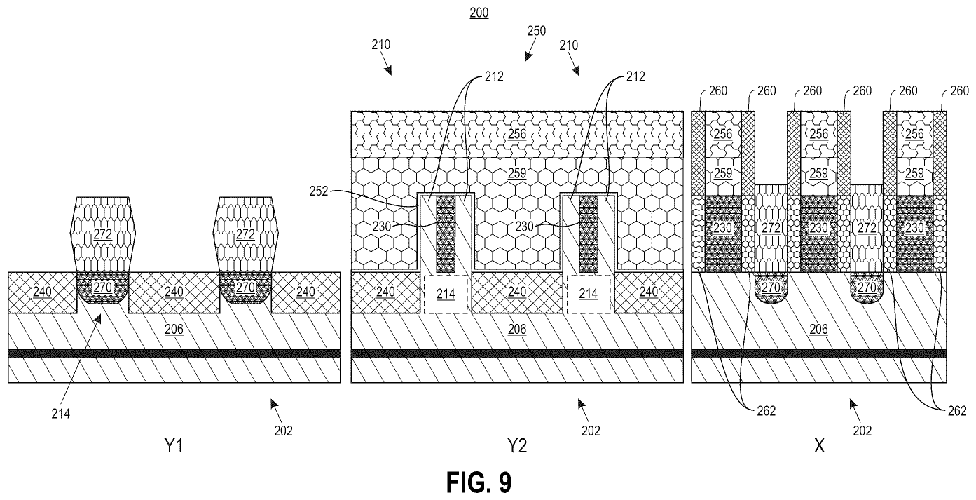

FIG. 9 depicts a fabrication cross-sectional view of semiconductor IC device 200 that includes or is to include FinFETs that have channel(s) that can have relatively different or variable channel heights, according to embodiments of the disclosure. At the present fabrication stage, sacrificial gate structures 250 may be formed, gate spacers 260 may be formed, gate inner spacer 262 may be formed, backside contact placeholders 270 may be formed, and source/drain (S/D) regions 272 may be formed.

The sacrificial gate structures 250 may include a sacrificial gate liner 252, a sacrificial gate 259, and a sacrificial gate cap 256. The sacrificial gate structures 250 may be formed by initially depositing a sacrificial gate liner layer (e.g., a dielectric, oxide, or the like) upon the one or more STI regions 240 and upon and around the one or more channel rows. The sacrificial gate structures 250 may further be formed by subsequently depositing a sacrificial gate layer (e.g., amorphous silicon, or the like) upon the sacrificial gate liner layer. The sacrificial gate structures 250 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 200.

The one or more sacrificial gate structures 250 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner 252, the sacrificial gate 259, and the sacrificial gate cap 256, respectively, of each of the one or more sacrificial gate structures 250.

The illustrated semiconductor IC device 200 may be further fabricated by forming gate spacers 260 around the sacrificial gate structures 250. The gate spacer(s) 260 may be formed by a conformal deposition of a dielectric material, such as silicon nitride, SiBCN, SiNC, SiN, SiCO, SiNOC, or a combination thereof, or the like, upon and around the one or more sacrificial gate structures 250 and upon and around the one or more channel rows. Subsequently, undesired portions of dielectric material may be removed while desired portions the dielectric material may be retained and thereby form the gate spacer(s) 260.

The illustrated semiconductor IC device 100 may be further fabricated by forming recesses or openings within the one or more channel rows between gate spacers 260 of neighboring sacrificial gate structures 250. In other words, a single channel row may be separated, by one or more recesses, into multiple channel stacks each located underneath a portion of respective sacrificial gate structure 250 and associated gate spacers 260.

The channel row recess or opening may be formed to a depth to stop at the top surface of the STI regions 240. The undesired portions of channel rows may be removed by etching or other subtractive removal techniques. As the gate spacers 260 and the sacrificial gate structures 250 may be utilized to protect the underlying portions of channel rows, respective sidewalls of the upper portions 212 of the pair of fins 210 and associated fin plug 230 may be substantially vertical and substantially coplanar with the outer sidewalls of the gate spacers 260 there above.

As used herein, “substantially vertical” sidewalls deviate from a direction normal to a major surface (e.g., top surface, etc.) of the substrate structure 202 by less than 5°, e.g., 0°, 1°, 2°, 3°, 4°, or 5°, including ranges between any of the foregoing values.

The illustrated semiconductor IC device 200 may be further fabricated by forming horizontal or lateral indents by laterally or horizontally removing respective portion(s) of the fin plug(s) 230 within the channel stacks. The indents may be formed by a reactive ion etch (RIE) process, which can remove portions of the fin plug(s) 230. The horizontal depth of the indents may be chosen to set a length for a replacement gate structure that is formed in place of one sacrificial gate structure 250. The directional RIE can use a boron-based chemistry or a chlorine-based chemistry, for example, which recesses or removes the exposed end portions of the fin plug(s) 230 (e.g., end portions of the fin plug(s) 230 directly below gate spacer 260). In alternative implementations, when the fin plug(s) 230 are not SiGe, the directional etch of the sacrificial the fin plug(s) 230 may generally be selective to the fins 210, gate spacers 260, STI regions 240, and/or substrate structure 202.

The illustrated semiconductor IC device 100 may be further fabricated by forming a respective gate inner spacer 262 within each indent. The one or more gate inner spacer 262 can be formed by ALD or CVD or any other suitable deposition technique that deposits a dielectric material within the indent(s), thereby forming the gate inner spacer 262. In some examples, the gate inner spacer 262 are composed of a low-K dielectric material (a material with a lower dielectric constant relative to SiO₂), SiN, SiO, SiBCN, SiOCN, SiCO, etc. or any other suitable dielectric material. In certain implementations, after the formation of the gate inner spacer 262, a directional etch process is performed to create substantially vertical sidewalls of the gate inner spacer 262 that are coplanar with the substantially vertical sidewalls or end surfaces of upper portions 212 of the pair of fins 210, of the gate spacers 260, or the like.

The illustrated semiconductor IC device 100 may be further fabricated by forming one or more backside contact placeholders 270 within the substrate structure 202 in between adjacent sacrificial gate structures 250 within a respective opening. In one example, a respective backside contact placeholder 270 may be formed in all opening location(s), such that a respective backside contact placeholder 270 is located underneath each S/D region 272.

If the recesses are not of sufficient depth, the one or more backside contact placeholders 270 may be formed by forming one or more backside contact placeholder openings within the substrate structure 202 generally in between adjacent sacrificial gate structures 250 and below the prior respective one or more openings. The one or more backside contact placeholders 270 may be further formed by epitaxially growing an epitaxial material from exposed substrate structure 202 surface(s) within the one or more backside contact placeholder(s) openings. In an example, the epitaxial material of the one or more backside contact placeholders 270 may be chosen to be etch selective to the material of the S/D region(s) 272, the material of the upper substrate 206, or the like.

In an example, as depicted, a barrier layer may be formed upon the backside contact placeholder 270 within the one or more backside contact placeholder(s) cavities. The barrier layer may be utilized to help protect or mask the associated backside contact placeholder 270 during the etching process(es). The barrier layer(s) may be epitaxially grown. For example, the one or more backside contact placeholders 270 may be SiGe and the barrier layer(s) may be Si.

The illustrated semiconductor IC device 100 may be further fabricated by forming one or more respective S/D regions 272 upon a respective backside contact placeholder 270 or barrier layer (if present). For example, p-doped S/D regions 272 may be formed in a first formation sequence and then n-doped S/D regions 272 may be formed in a second formation sequence, or vice versa.

Each S/D region 272 may form either a source or a drain, respectively, of a respective FinFET and is connected to respective end surfaces of upper portions 212 of the pair of fins 210 of one or more nanolayer stacks. Each S/D region 272 is composed of a semiconductor material and a dopant. As used herein, a “source/drain” region can be a source region or a drain region depending on subsequent wiring and application of voltages during operation of the applicable transistor.

The semiconductor material that provides each of the S/D regions 272 may be composed of one of the semiconductor materials mentioned above for the semiconductor structure 202. For example, the semiconductor material that provides the S/D region 272 can be compositionally the same, or compositionally different from each fin 210. The dopant that is present in the S/D regions 272 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 272 are referred to herein as being p-doped and when the semiconductor material is doped with a n-type dopant, the resulting S/D regions 272 are referred to herein as being n-doped.

The S/D regions 272 may be epitaxially grown or formed. In some examples, the S/D regions 272 are formed by in-situ doped epitaxial growth. The use of an in-situ doping process is merely an example. For instance, one may instead employ an ex-situ process to introduce dopants into the S/D regions 272. Other doping techniques can be used to incorporate dopants in the S/D regions 272.

In some examples, the epitaxial growth that forms the S/D region 272 occurs or is promoted from the top surface of upper substrate 206, from the upper surface of backside contact placeholders 270 (or barrier layer thereupon), from the exposed surface(s) of the fins 210, or the like, while epitaxial growth may be limited or does not occur from neighboring STI regions 240.

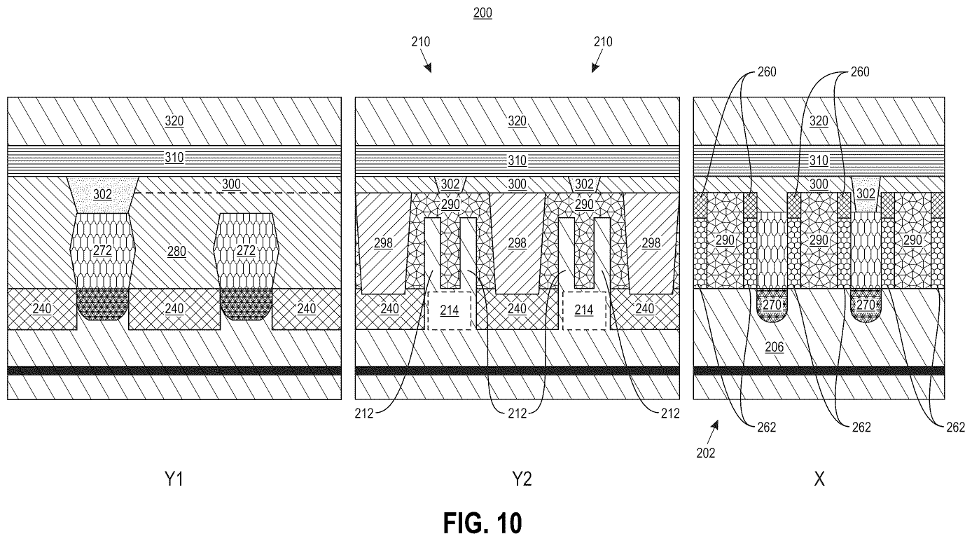

FIG. 10 depicts a fabrication cross-sectional view of semiconductor IC device 200 that includes or is to include FinFETs that have channel(s) that can have relatively different or variable channel heights, according to embodiments of the disclosure. At the present fabrication stage, ILD 280 may be formed, sacrificial gate structures 250 may be removed, replacement gate structures 290 may be formed in place of the removed sacrificial gate structures 250, gate cut regions 298 may be formed, ILD 300 may be formed, frontside contacts 302 may be formed, a frontside BEOL network 310 may be formed, and a carrier wafer 320 may be bonded to the semiconductor IC device 200.

ILD 280 may be formed on the one or more S/D regions 272, upon the top surface of STI regions 240, upon the gate spacers 260, or the like. ILD 280 may be formed by depositing a dielectric material, such as silicon oxide, silicon nitride, SiBCN, SiNC, SiN, SiCO, SiNOC, or a combination thereof, or the like, as a blanket layer. In an embodiment, ILD 280 may be formed to a thickness above the top surface of semiconductor device 200 and subsequently planarized by a chemical mechanical polish (CMP) or etch, such that the top surface of sacrificial gate structure 250 is exposed (e.g., sacrificial gate cap 256 is removed by the CMP) and is coplanar with a top surface of the sacrificial ILD 280 and with a top surface of gate spacers 260.

Upon exposing a portion of the sacrificial gate structure 250, the remaining sacrificial gate structure 250 may be removed by an etch. The removal of sacrificial gate structure 250 may expose the respective upper portion(s) 212 of the pair of fins 210 between gate spacers 260, and/or the like.

A replacement gate structure 290 may then formed in place of the removed sacrificial gate structure 250 in between gate spacers 260 and upon and around the respective upper portion(s) 212 of the pair of fins 210. The replacement gate structure 290 can include the gate dielectric (not shown) and replacement gate material(s). The gate dielectric can be the gate dielectric associated with the replacement gate structure 250 or if removed, a subsequent gate dielectric that can comprise any suitable dielectric material, including but not limited to silicon oxide, silicon nitride, silicon oxynitride, high-k materials, or any combination of these materials. The gate dielectric can be formed by any suitable deposition process or the like. In some embodiments, the gate dielectric has a thickness ranging from 1 nm to 5 nm, although less thickness and greater thickness are also conceived.

Replacement gate structure 190 can comprise any suitable conducting material, including but not limited to, doped polycrystalline or amorphous silicon, germanium, silicon germanium, a metal (e.g., tungsten (W), titanium (Ti), tantalum (Ta), ruthenium (Ru), hafnium (Hf), zirconium (Zr), cobalt (Co), nickel (Ni), copper (Cu), aluminum (Al), platinum (Pt), tin (Sn), silver (Ag), gold (Au), a conducting metallic compound material (e.g., tantalum nitride (TaN), titanium nitride (TiN), tantalum carbide (TaC), titanium carbide (TiC), titanium aluminum carbide (TiAlC), tungsten silicide (WSi), tungsten nitride (WN), ruthenium oxide (RuO2), cobalt silicide (CoSi), nickel silicide (NiSi)), transition metal aluminides (e.g. Ti3Al, ZrAl), TaC, TaMgC, carbon nanotube, conductive carbon, graphene, or any suitable combination of these materials.

In some embodiments, the replacement gate structure 190 may further comprise a workfunction layer (not shown). The workfunction setting layer can be a workfunction metal (WFM). The WFM can be formed by any suitable process or any suitable combination of multiple processes, including but not limited to, atomic layer deposition (ALD), chemical vapor deposition (CVD), physical vapor deposition (PVD), sputtering, plating, evaporation, ion beam deposition, electron beam deposition, laser assisted deposition, chemical solution deposition, etc.

The replacement gate structure 290 may be formed by initially forming the gate dielectric layer between gate spacers 260 around the upper portion(s) 212 of the pair of fins 210 and upon the top surface of STI regions 240. The replacement gate structure 290 may further be formed by subsequently forming a gate conductor layer upon the gate dielectric layer. The gate conductor layer and gate dielectric layer may be patterned using lithography and etch process to remove undesired portions and retain desired portion(s), respectively. The retained desired portion(s) of the gate conductor layer and gate dielectric layer may form the replacement gate structure 290. A CMP, etch process, or another subtractive removal technique, may remove undesired portions of replacement gate structure 290, such that a top surface of replacement gate structure 290 is coplanar with the top surface of gate spacer 260, ILD 280, or the like. In some implementations, the replacement gate structure 190 can be recessed below the top surface of semiconductor device 200 and a dielectric gate cap (not shown) can be formed upon the recessed replacement gate structure 190. For clarity, to achieve expected FinFET functionality, the replacement gate structure 190 may control charge carrier flow between the upper portion(s) 212 of the pair of fins 210 between the associated S/D regions 272. The replacement gate structures 290 may be respective tri-gate in that such replacement gate structures 290 contacts three sides of the upper portion(s) 212 of the pair of fins 210.

The gate cut region 298 may be formed by forming and patterning a gate cut mask and utilizing such to forming gate cut region openings within or across the replacement gate structures 290. The gate cut region openings may have a well or bottom surface within an underlying STI region 240. The pattern transfer etching process to form the gate cut opening may be an anisotropic etch. In certain embodiments, a dry etching process such as, for example, RIE can be used. In other embodiments, a wet chemical etchant can be used. In still further embodiments, a combination of dry etching and wet etching can be used. The gate cut region 298 may be formed by depositing a gate cut dielectric material, such as, for example, porous silicates, carbon doped oxides, silicon dioxides, silicon nitrides, silicon oxynitrides, or other dielectric materials, within the gate cut region openings. Any appropriate deposition technique for forming the gate cut dielectric layer can be utilized. The gate cut dielectric layer can be formed using, for example, CVD, PECVD, ALD, flowable CVD, spin-on dielectrics, or PVD.

For clarity, the gate cut region 298 may divides and/or electrically separates one or more replacement gate structures 290 into a first gate or gate structure and a second gate or gate structure. The first gate or gate structure may be associated with the first FinFET and the second gate or gate structure may be associated with the second FinFET. Subsequently, the semiconductor IC device 200 may be planarized by a CMP, or the like. Therefore, respective top surfaces of the ILD 280, replacement gate structures 290, gate spacers 260, and gate cut regions 298 may be substantially horizontal and/or substantially coplanar.

The illustrated semiconductor IC device 200 may be further fabricated by forming ILD 300 upon the ILD 28, upon the replacement gate structures 290, upon the gate spacers 260. The ILD 300 may be formed by depositing a dielectric material, such as silicon oxide, silicon nitride, SiBCN, SiNC, SiN, SiCO, SiNOC, or a combination thereof, or the like, as a blanket layer. In an embodiment, ILD 300 may be planarized by a CMP or etch, above the top surface of replacement gate structures 290.

The illustrated semiconductor IC device 200 may be further fabricated by forming frontside contacts 302 within the ILD 300 and/or the ILD 280. The frontside contacts 302 may be formed by patterning respective frontside contact openings within the ILD layer(s), respectively, from the frontside (i.e., from above the semiconductor IC device 200, as depicted, downward to respective structures thereof). The frontside contacts 302 may be in direct or indirect physical and electrical contact and/or may physically meld with respective material(s) of one or more regions of the semiconductor IC device 200.

The frontside contact(s) 302 may be formed by depositing conductive material such as metal into the respective frontside contact opening(s). In an example, frontside contact(s) 302 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 302 are fabricated in middle-of-line (MOL) fabrication operations and may be illustrations of MOL frontside contacts.

In the semiconductor IC device fabrication industry, there are three sections referred to in a build: front-end-of-line (FEOL), back-end-of-line (BEOL), and the section that connects those two together, the middle-of-line (MOL). The FEOL is made up of the semiconductor devices, e.g., transistors, the BEOL is made up of interconnects and wiring, and the MOL is an interconnect between the FEOL and BEOL that includes material to prevent the diffusion of BEOL metals to FEOL devices.

BEOL is the second portion of IC fabrication where the individual devices (e.g., transistors, capacitors, resistors, etc.) become interconnected with wiring on the semiconductor IC device, e.g., the metallization layer or layers of a wafer. BEOL includes contacts, insulating layers (dielectrics), metal levels, and bonding sites for chip-to-package connections. In the BEOL, part of the fabrication stage contacts (pads), interconnect wires, vias and dielectric structures are formed. For modern IC processes, more than one metal layers may be added in the BEOL. In the present example, there are multiple BEOL levels each on opposites sides of the semiconductor IC device 200. First, a frontside BEOL network 310 is formed on the frontside of the semiconductor device 200. Subsequently, a backside BEOL network may be formed.

In the depicted example, the frontside BEOL network 310 is formed over the ILD 300 and upon the frontside contacts 302. Respective wires within the frontside BEOL network 310 may be electrically connected to the one or more S/D regions 272, to the one or more replacement gate structure(s) 290, or the like, by a respective frontside contact(s) 302. For example, respective wire(s) within the frontside BEOL network 310 may be electrically connected to appropriate S/D regions 272 by a frontside contact 302, and another different group of respective wire(s) within the frontside BEOL network 310 may be electrically connected to appropriate replacement gate structures 290, etc.

The frontside BEOL network 310 can include one or more interconnect dielectric material layers (including one of the dielectric materials mentioned above for the frontside ILD 176) and contains conductive wires (the conductive wires can be composed of any electrically conductive metal or electrically conductive metal alloy) embedded therein. In some embodiments, the frontside conductive wires within the frontside BEOL network 310 are composed of Cu. The frontside BEOL network 310 can include “x” numbers of frontside metal levels, wherein “x” is an integer starting from 1. The frontside BEOL network 310 may further contain conductive pads that are connected to one or more of the conductive wires and may be used to connect the semiconductor IC device 200 to an external and/or higher-level structure, such as a chip carrier, motherboard, or the like.

The illustrated semiconductor IC device 200 may be further fabricated by bonding carrier wafer 320 to the frontside BEOL network 310. The carrier wafer 320 can include one of the semiconductor materials mentioned above for the semiconductor structure and the carrier wafer 320 may be attached to the semiconductor IC device 200 by a wafer-to-wafer bonding technique.

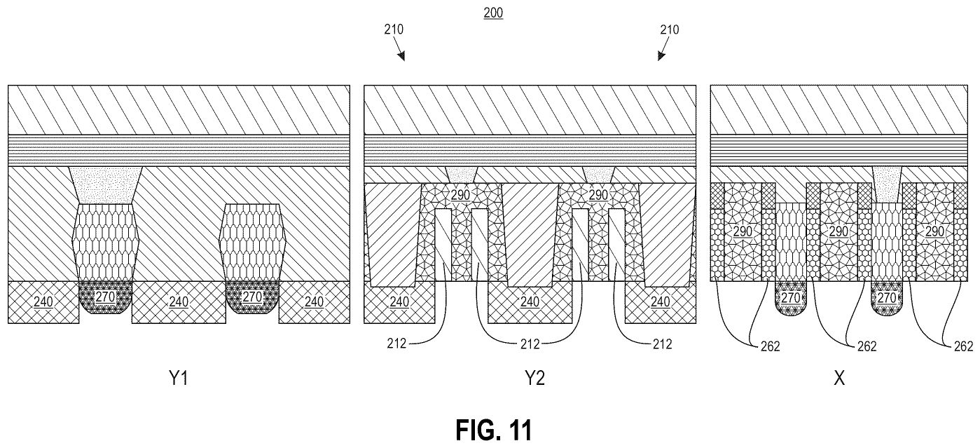

FIG. 11 depicts an fabrication cross-sectional view of semiconductor IC device 200 that includes or is to include FinFETs that have channel(s) that can have relatively different or variable channel heights, according to embodiments of the disclosure. At the present fabrication stage, the substrate structure 202 may be removed.

The substrate structure 202 may be removed by flipping the semiconductor IC device 200 (not shown) and removing the lower substrate 204 using any removal technique, such as a combination of wafer grinding, CMP, dry, and/or wet etch. In the example depicted, lower substrate 204 is removed by an etch that utilizes etch stop layer 205 as the etch stop. In this example, removal of lower substrate 204 exposes the bottom surface of etch stop layer 205.

The substrate structure 202 may be further removed by removing the etch stop layer 205 and the upper substrate 206. The etch stop layer 205 may be removed by a subtractive removal technique such as a CMP, dry and/or wet etch. Upon removal of the etch stop layer 205, the bottom surface upper substrate 206 is exposed. The removal of etch stop layer 205 may be selective to the material of upper substrate 206. For example, etch stop layer 205 is removed by an etch that utilizes upper substrate 206 as the etch stop.

The upper substrate 206 may be removed by an appropriate substrative removal technique, such as an etch. The etch may be timed or otherwise controlled to remove the material of substrate 206 selective to the STI regions 240, to the backside contact placeholders 270, to the replacement gate structures 290, to the upper portion(s) 212 of the pair of fins 210, and/or to the gate inner spacers 262, or the like.

In an example, the etch that removes the upper substrate 206 may be controlled to result in the respective bottom surfaces of the upper portion(s) 212 of the pair of fins 210 to be coplanar with the bottom surfaces of the replacement gate structures 290, the top surfaces of the STI regions 240, or the like. In other words, the etch that removes the upper substrate 206 may be controlled to remove the lower portion 214 of the pair of fins 210. As such, at the present stage, the upper portion(s) 212 of the pair of fins 210 and the fins 210 generally may be synonymous, as the lower portion 214 is removed.

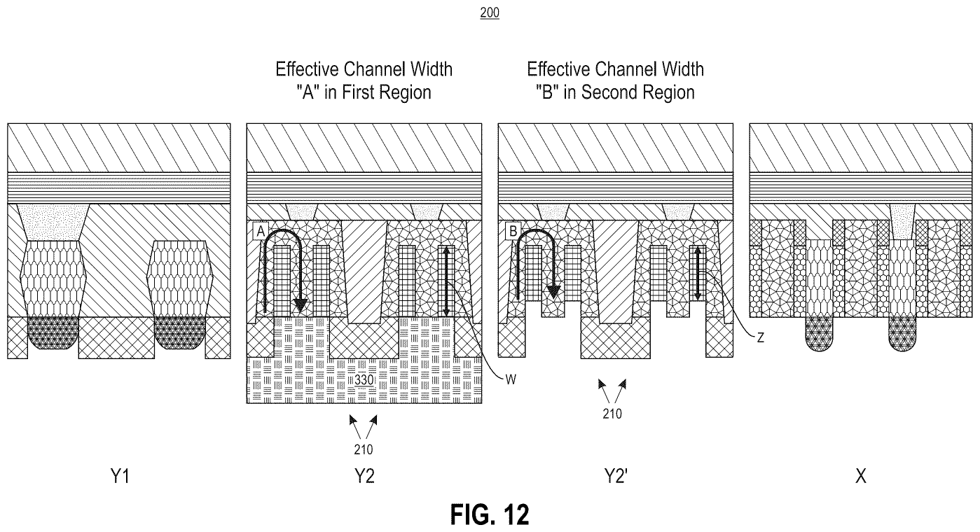

FIG. 12 depicts a fabrication cross-sectional view of semiconductor IC device 200 that includes FinFETs that have channels (i.e., fins 210) that can have relatively different or variable channel heights, according to embodiments of the disclosure. At the present fabrication stage, some of the fins 210 within a second Y2 cross sectional plane region may be further recessed from the backside while some of the fins 210 within a first Y2 cross sectional plane region may be protected.

The first Y2 cross sectional plane region may be protected by depositing a mask 330, such as a dielectric, OPL, or the like. The mask may be patterned and opened in the second Y2 cross sectional plane region to expose the second Y2 cross sectional plane region.

In an example, an etch that further removes the fins 210 in the exposed second Y2 cross sectional plane region may cause such fins 210 to be recessed above the bottom surface of their associated replacement gate structures 290. The etch may be controlled, timed, or the like, to achieve the desired fin 210 material removal. Consequently, the bottom surface of the recessed fins 210 may be inset between the bottom surface and the top surface of their associated replacement gate structures 290.

Consequently, the first Y2 cross sectional plane region and the second Y2 cross sectional plane region include one or more transistors (e.g., FinFETs) with fins 210 that have relatively different or variable channel heights W, Z. For example, the first Y2 cross sectional plane region has first fin(s) 210 that has a first fin height W and the second Y2 cross sectional plane region has second fin(s) 210 that has a second fin height Z that is less than the first fin height W. Similarly, the fins 210 within the different regions may have relatively different effective channel widths A, B. For example, the first Y2 cross sectional plane region has first fin(s) 210 that has a first effective channel width A (i.e., two times the vertical channel height W plus the horizontal channel thickness) and the second Y2 cross sectional plane region has second fin(s) 210 that has a first effective channel width B (i.e., two times the vertical channel height Z plus the horizontal channel thickness) that is less than the first effective channel width A.

The semiconductor IC device 200 provides flexibility in achieving variable or different fin heights W, Z in different areas or regions of the semiconductor IC device 200, which may increase semiconductor IC device 200 fabrication efficiency, yield, and/or performance. Subsequenlty, the mask 330 may be removed by a substrative removal technique, such as an etch, OPL ash, or the like.

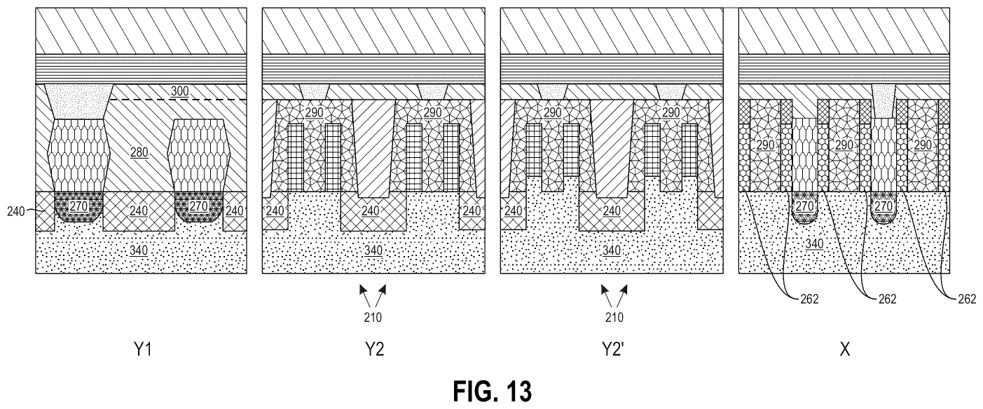

FIG. 13 depicts a fabrication cross-sectional view of semiconductor IC device 200 that includes FinFETs that have channels that have relatively different or variable channel heights, according to embodiments of the disclosure. At the present fabrication stage, a backside ILD 340 may be formed upon the backside of the semiconductor IC device 200.

The backside ILD 340 may be formed upon the backside contact placeholder(s) 270, upon the STI regions 240, upon the backside of the replacement gate structures 290, upon the backsides of the fins 210, upon the backside of the inner gate spacers 262, and/or the like. The backside ILD 340 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 340 can be utilized. The backside ILD 340 can be formed using, for example, CVD, PECVD, ALD, flowable CVD, spin-on dielectrics, or PVD.

In an example, the material of the backside ILD 340 may be the same material as the ILD 280 and/or as the ILD 300. In alternative examples, the material(s) may be different. For example, the material of the backside ILD 340 may be chosen to achieve a predetermined electrical isolation metric that the dielectric material of the ILD 280 and/or the ILD 300 could not achieve, if utilized. For example, frontside ILD 280 and/or the ILD 300 may be silicon dioxide and the backside ILD 340 may be a low-K dielectric material.

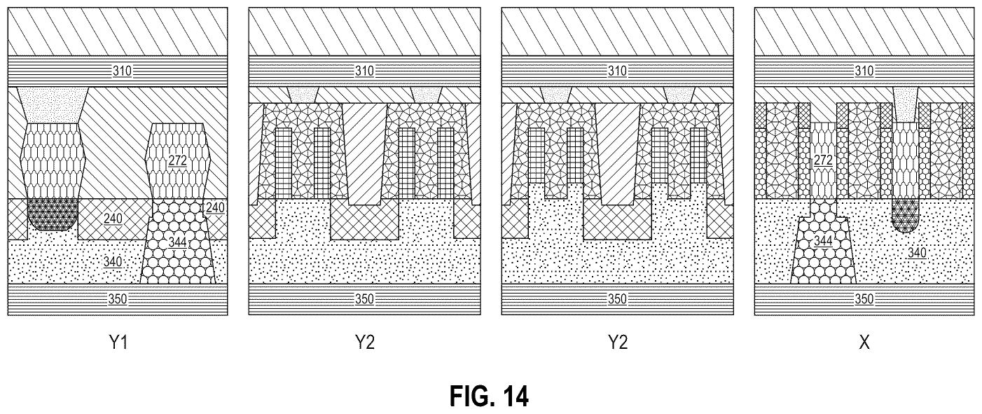

FIG. 14 depicts a fabrication cross-sectional view of semiconductor IC device 200 that includes FinFETs that have channels that have relatively different or variable channel heights, according to embodiments of the disclosure. At the present fabrication stage, backside contact(s) 344 may be formed and a backside BEOL network 350 may be formed.

Backside contacts 344 may be formed by forming an associated backside contact opening within the backside ILD 340. The backside contact opening(s) may be formed by the same or shared lithography and etch process(es), or sequential lithography and etch processes. In such process(es), a mask (not shown) may be applied to the backside of the semiconductor IC device 200 and patterned. Openings in the patterned mask may sequentially expose the portion(s) of the underlying material(s) that are to be removed while other protected portions of semiconductor IC device 200 may be protected and retained.

The backside contact opening(s) may be formed to expose the associated backside contact placeholder 270 there above (e.g., the backside contact placeholder 270 that is below a S/D region 272 that is not connected to the frontside BEOL network 310). The backside contact placeholder(s) 270 that are exposed by respective backside contact opening(s) may be removed by a substrative removal technique, such as an etch, and are therefore not depicted.

Alternatively, the exposed S/D region(s) 272 may be exposed and at least partially gouged, or in other words, a lower portion of the exposed S/D region 272 is removed while an upper portion of the exposed S/D region(s) 272 is retained. The lower portion of the S/D region(s) 272 may be removed by a subtractive removal technique, such as an etch.

Respective backside contact(s) 344 may be formed within a respective backside contact opening against the associated S/D region 272 by depositing conductive material, such as metal, therein. In an example, backside contact(s) 344 may be simultaneously formed by depositing a liner, such as Ni, NiPt or Ti, etc. onto the backside of semiconductor IC device 200 and into the backside contact openings, depositing an adhesion liner, such as TiN, TaN, etc. upon the liner, and by depositing a conductive fill, such as Al, Ru, W, Co, Cu, etc. upon the adhesion liner. Subsequently, a planarization process, such as a CMP, may expose a bottom surface of the backside ILD 340. As a result, the respective bottom surfaces of backside contact(s) 344 and backside ILD 340 may be substantially horizontal and/or substantially coplanar.

The backside BEOL network 350, such as a backside power distribution network (BSPDN) may be formed upon the backside contact(s) 344, upon the backside ILD 340. The backside BEOL network 350 may include signal wires for signal routing and power wires for providing power potential (e.g., VDD, VSS, etc.). The backside BEOL network 350 may allow for the distribution of power wires and signal wires between both the frontside and backside of the semiconductor IC device. The backside BEOL network 350 may further allow for the full or partial decoupling of signal routing and/or power routing and/or allows for dividing or splitting power wires and/or signal wires between both the frontside and backside of the semiconductor IC device 200. By incorporating the backside BEOL network 350, routing congestion may be reduced, which may lead to further semiconductor IC device 200 scaling. For example, semiconductor IC devices 200 that incorporate a backside BEOL network can result in a 30% area reduction and improved current-resistance (IR) drop compared to typical semiconductor IC devices that include solely a frontside BEOL network.

The backside BEOL network 350 may be electrically connected to the one or more S/D regions 272 by way of a particular backside contact 344. For example, a first backside wire within the backside BEOL network 350 may be electrically connected the backside contact 344, or the like.

The backside BEOL network 350 can include one or more interconnect dielectric material layers and contains backside conductive wires and/or interconnects, such as VIAs, embedded therein. In some embodiments, the backside wires within the backside BEOL network 350 are composed of Cu. The backside BEOL network 350 can include “x” numbers of backside metal levels, wherein “x” is an integer starting from 1. If not included in frontside BEOL network 310, backside BEOL network 350 may further contain conductive pads that are connected to one or more of the backside metal wires and may be used to connect the semiconductor IC device 200 to the external and/or higher-level structure.

In an example, signal routing and power routing is effectively split between the frontside BEOL network 182 and the backside BEOL network 350. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 200 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

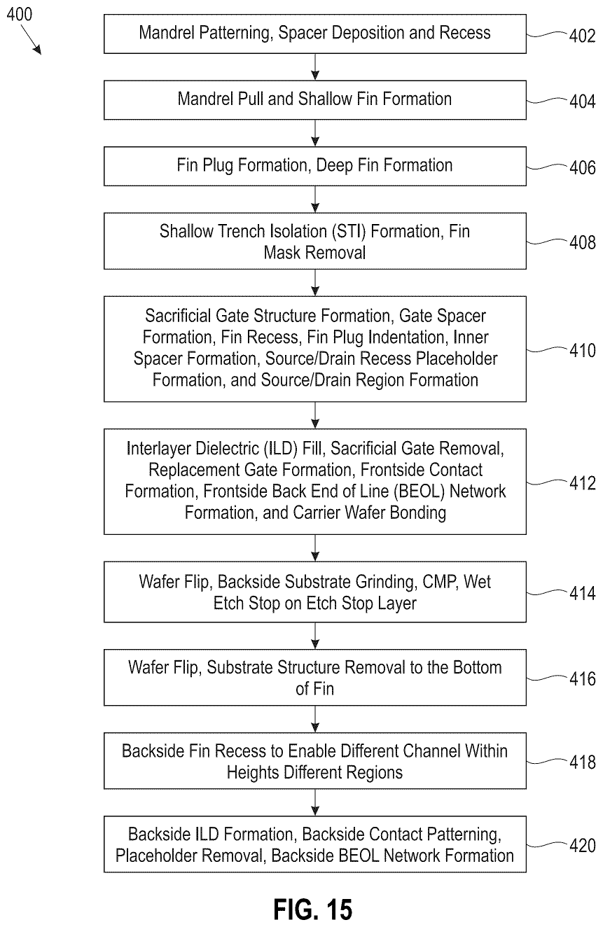

FIG. 15 depicts a method 400 of fabricating semiconductor device that that includes channels that have relatively different or variable channel heights, according to embodiments of the disclosure. Method 400 begins at block 402 by forming one or more fin mandrels 220 and one or more SIT spacers 224 over substrate structure 202. Method 400 may continue, at block 404, with a fin mandrel 220 pull and shallow fin formation. For example, the fin mandrels 220 are removed and the upper portion(s) 212 of the pair of fins 210 are formed under the SIT spacers 224 by a substrate structure 202 recess.

Method 400 may continue, at block 406, with fin plug 230 formation and deep fin formation. For example, fin plugs 230 are formed and structurally tie together the upper portion(s) 212 of the pair of fins 210. The fin plug 230 and the SIT spacers 224 may protect the underlying regions during a further substrate structure 202 recess that effectively forms the lower portion 214 of the pair of fins 210.

Method 400 may continue, at block 408, with forming STI regions 240 and removing the fin mask (i.e., SIT spacers 224). Method 400 may continue, at block 410, with forming sacrificial gate structures 250, with forming gate spacers 260, with recessing the channel row (i.e., pair of fins 210 and fin plug 230 therebetween) between adjacent sacrificial gate structures 250, with horizontally indenting the fin plug 230, with forming an inner gate spacer 262 within the horizontal indent, with forming a backside contact placeholder 270, and with forming S/D regions 272.

Method 400 may continue, at block 412, with forming ILD 280, with sacrificial gate structure 250 removal, with replacement gate structure 290 formation, with gate cut region 298 formation, with ILD 300 formation, with frontside contact 302 formation, with frontside BEOL network 310 formation, and with attaching carrier wafer 320.

Method 400 may continue, at block 414 and at block 416, with flipping the carrier wafer and with backside substrate structure 202 removal (e.g., substrate grinding, CMP(s), wet etch(es), or the like) that stops at the bottom surface of the upper portion(s) 212 of fins 210. For example, the lower substrate 204 and the etch stop layer 205 can be sequentially removed. Next, the upper substrate 206 may be partially removed stopping at the bottom surface of the upper portion(s) 212 of fins 210.

Method 400 may continue, at block 418, with selectively recessing the backside of some of the fins 210 to enable different channel heights within different regions of the semiconductor IC device. For example, after the selective recess of the backside of some of the fins 210, the semiconductor IC device includes a first region with a first fin that has a first fin height and a second region having a fin that has a second fin height that is less than the first fin height.

Method 400 may continue, at block 420, with backside ILD 340 formation, with backside contact patterning to expose a backside contact placeholder 370, with backside contact placeholder 370 removal, with backside contact 344 formation, and with backside BEOL network 350 formation.

The descriptions of the various embodiments of the disclosure have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first region comprising a first fin upon a backside interlayer dielectric (ILD), the first fin having a first fin height; and
a second region comprising a second fin upon the backside ILD, the second fin having a second fin height that is less than the first fin height.

2. The semiconductor IC device of claim 1, wherein a top surface of the first fin is coplanar with a top surface of the second fin.

3. The semiconductor IC device of claim 2, wherein first shallow trench isolation (STI) regions at least partially bound the first region, and wherein the first region further comprises a first FinFET comprising first source/drain (S/D) regions and the first fin.

4. The semiconductor IC device of claim 3, wherein second STI regions at least partially bound the second region, and wherein the second region further comprises a second FinFET comprising second source/drain (S/D) regions and the second fin.

5. The semiconductor IC device of claim 4, wherein a bottom surface of the first fin is substantially coplanar with a top surface of the first STI regions.

6. The semiconductor IC device of claim 5, wherein a bottom surface of the second fin is above a top surface of the second STI regions.

7. The semiconductor IC device of claim 6, wherein the top surface of the first STI regions and the top surface of the second STI regions are substantially coplanar.

8. The semiconductor IC device of claim 7, wherein the first FinFET further comprises a first gate and wherein a bottom surface of the first gate is substantially coplanar with the bottom surface of the first fin.

9. The semiconductor IC device of claim 8, wherein the second FinFET further comprises a second gate and wherein a bottom surface of the second gate is substantially coplanar with the top surface of the second STI regions.

10. The semiconductor IC device of claim 9, wherein the backside ILD comprises a backside ILD portion between the bottom surface of the second fin and the top surface of the second STI regions.

11. The semiconductor IC device of claim 10, further comprising:
a frontside back end of line (BEOL) network; and
a backside BEOL network.

12. The semiconductor IC device of claim 11, wherein the first gate and the second gate are respectively electrically connected to the frontside BEOL network.

13. The semiconductor IC device of claim 12, wherein one of the first S/D regions is electrically connected to the frontside BEOL network by a frontside contact and another of the first S/D regions is electrically connected to the backside BEOL network by a backside contact.

14. The semiconductor IC device of claim 13, wherein the first FinFET further comprises a first gate inner spacer in contact with a sidewall of the first gate and with a sidewall of one of the first S/D regions and a second gate inner spacer in contact with an opposite sidewall of the first gate and with a sidewall of another of the first S/D regions.

15. A semiconductor integrated circuit (IC) device comprising:
a first FinFET comprising a first fin upon a backside interlayer dielectric (ILD) comprising a first effective channel width; and
a second FinFET comprising a second fin upon the backside ILD comprising a second effective channel width that is less than the first effective channel width.

16. The semiconductor IC device of claim 15, wherein a top surface of the first fin is coplanar with a top surface of the second fin.

17. The semiconductor IC device of claim 16, wherein a first fin thickness is substantially the same as a second fin thickness.

18. A semiconductor integrated circuit (IC) device fabrication method comprising:
forming a pair of fins within a substrate structure;
forming a fin plug between the pair of fins;
after forming the fin plug, forming shallow trench isolation (STI) openings within the substrate structure below and adjacent to the pair of fins; and
forming a respective STI region within the STI openings.

19. The semiconductor IC device fabrication method of claim 18, further comprising:
from a backside of the semiconductor IC device, removing the substrate structure between the STI regions below the pair of fins.

20. The semiconductor IC device fabrication method of claim 19, wherein removing the substrate structure between the STI regions below the pair of fins further comprises:
further removing a respective portion of the pair of fins above the STI regions.
